(19) United States
(12) Patent Application Publication
(10) Pub. No.: US 2008/0093532 A1
(43) Pub. Date: Apr. 24, 2008

(54) Memory card having an information display function using an external light source

(76) Inventor: Kwang-Chol Choe, Geumcheon-gu (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/798,409

(22) Filed: May 14, 2007

(30) Foreign Application Priority Data
Oct. 24, 2006 (KR) 10-2006-0103209

(51) Int. Cl. G11C 99/00; H01J 40/14

(52) U.S. Cl. 250/206; 365/244

(57) ABSTRACT

A memory card including a first memory responsible for the main memory of the memory card, a memory control unit adapted to control the operation of the first memory, a photoelectric voltage generating unit adapted to generate a voltage corresponding to light irradiated externally via photoelectric conversion, a display unit having a second memory adapted to store information set in advance and adapted to display the information set in advance, and a display control unit adapted to control the operation of the display unit. The method of displaying information includes generating a voltage corresponding to light irradiated externally via photoelectric conversion and displaying information set in advance via a display unit of the memory card using the voltage by photoelectric conversion.

### CROSS-REFERENCE TO RELATED APPLICATION

This application claims priority under 35 U.S.C. § 119 from Korean Patent Application No. 10-2006-0103209 filed on Oct. 24, 2006 the disclosure of which is hereby incorporated by reference in its entirety.

### BACKGROUND OF THE INVENTION

1. Field of the Invention

Embodiments of the present invention relate to a memory card, and more particularly, to a memory card having an information display function using an external light source and associated method.

2. Description of the Related Art

As portable electronic devices are developed, a demand for data storage has rapidly increased. Widely used memory storage devices include non-volatile memory such as flash EEPROM which is neither the conventional hard disk nor a hard disk drive type. The non-volatile memory is usually in the form of a detachable memory card, such as a smart card. These memory cards are suitable for use in various types of electronic devices, for example, digital cameras, portable game devices, camcorders, mobile telephones, televisions, and even printers.

A typical memory card is composed of non-volatile memory of a NAND type or a NOR type adapted to store data, a memory control unit adapted to control the operation of the non-volatile memory, and an input/output interface used to connect to portable devices. The memory card keeps a standardized form for the same products for mutual transposition between portable devices. After being separated from a portable device and connected to a PC, the memory card exchanges information stored in the memory card with the PC in an upload/download form. In addition, when the fixed memory capacity of the memory card fills up, the memory card secures a capacity of available memory by erasing unnecessary information or storing information from the memory card into other devices through the PC or portable device. However, to check how much memory capacity is left in a memory card, the memory card must be connected to a PC or portable device. Sometimes it is inconvenient or impossible to confirm the amount of remaining memory capacity of the memory card when, for example, a PC or external device is unavailable.

One proposed solution to this problem requires that the memory card be connected to an external and the remaining memory capacity of the memory card is checked through the external device or displayed on the memory card before power to the external device is shut off. However, this solution requires additional equipment to confirm the remaining memory capacity of the memory card, and the remaining memory capacity may be displayed, but not based on a user's choice. This solution has the drawback of requiring additional equipment, as well as limiting a user's accessibility to the remaining memory capacity of a memory card.

### SUMMARY OF THE INVENTION

Exemplary embodiments of the present invention are directed to a memory card capable of displaying information using an external light source to generate a voltage generated by photoelectric conversion. In an exemplary embodiment, the memory card includes a first memory responsible for a main memory function of the memory card. A memory control unit is adapted to control operation of the first memory. A photoelectric voltage generation unit is adapted to generate a voltage corresponding to light irradiated externally onto the memory card through photoelectric conversion. A display unit has a second memory adapted to store preset information and adapted to display this stored information using the voltage generated by the photoelectric voltage generation unit. A display control unit is also used to control operation of the display unit. Another exemplary embodiment includes a method of displaying information of a memory card using an external light source which includes generating a voltage corresponding to light irradiated externally onto the memory card through photoelectric conversion. This information may be stored in advance and displayed via a display unit of the memory card using the generated voltage.

### BRIEF DESCRIPTION OF THE DRAWINGS

FIG. 1 is a diagram illustrating a photoelectric cell;

FIG. 2 is a flowchart illustrating a method of displaying remaining memory capacity using an external light source according to an embodiment the present invention;

FIGS. 3A to 3D illustrate memory cards illustrating embodiments of a display unit and a photoelectric voltage generating unit in accordance with the present invention.

FIGS. 4A to 4C illustrate embodiment, which display the used memory capacity of a memory card in accordance with the present invention.

FIGS. 5A to 5C illustrate embodiments which display the remaining memory capacity of a memory card in accordance with the present invention.

FIG. 6 is a block diagram of a memory card in accordance with the present invention.

FIG. 7 is a block diagram of a memory card in accordance with the present invention.

FIG. 8 is a block diagram of a memory card in accordance with the present invention.

### DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

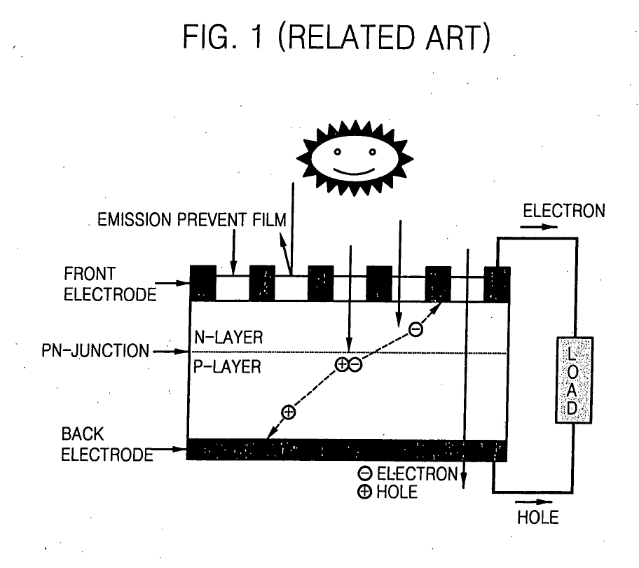

FIG. 1 illustrates a photo cell, for example a silicone cell that generates an electric signal via photoelectric conversion after receiving light energy. When light irradiates from outside the photoelectric cell, the associated light energy creates electron-hole pairs in a photo diode, each massed in different directions, to form a P-N junction structure. Each electron and hole obtain electromotive force (EMF) by forming an electrode in locations where each electron and hole is concentrated to produce a predetermined amount of electricity. Alternatively, a selenium photo-cell, or suboxidized photo-cell utilizing metal to semiconductor contact may be employed.

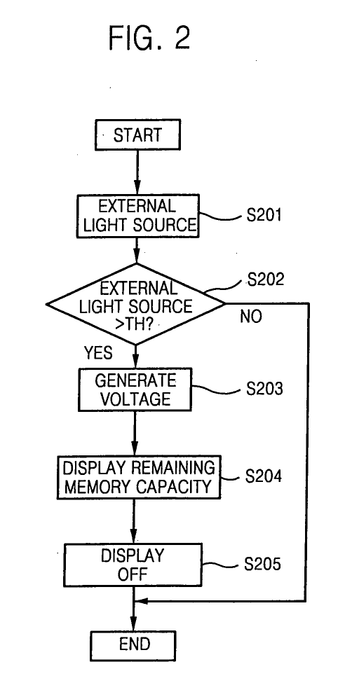

FIG. 2 is a flowchart illustrating a method of displaying the remaining memory capacity of a memory card (such as secure digital SD card, multi-media card MMC, memory stick, compacfflash™, xD-picture card, or smartmedia™) using an external light source. When a user irradiates external light using a light source such as a laser, a fluorescent light, or a solar photovoltaic, etc. to a photoelectric conversion unit (or a photoelectric voltage generating unit) located on the surface of the memory card, the photoelectric voltage generating unit performs a photoelectric conversion at step S201. The photoelectric voltage generating unit compares a degree of light with a predetermined reference level TH at step S202 and generates a voltage when the irradiated light degree exceeds the reference level TH at step S203. However, when the degree of irradiated light is less than the predetermined level TH, a voltage generation is automatically stopped and the voltage generated by the photoelectric voltage generating unit may be stored in a charge storage element, for example, a capacitor located inside the memory card. However, when light is irradiated onto the photoelectric voltage generating unit unintentionally or when the degree of light is less than reference level TH, it is unnecessary to display the remaining memory capacity of the memory card.

Alternatively, it may be desirable to differentiate the volume of light irradiated according to the amount and kind of information that a user requires. For example, information displayed through a display unit of the memory card may include not only the remaining memory capacity, but also user information such as contact information in case the memory card is lost. In this manner, when irradiating adequate light to a memory card after displaying various pieces of information according to the degree of light irradiated to a memory card or setting an operation mode of the memory card through a selection unit such as a level or a switch on the outside or the surface of the memory card, relevant information may be displayed.

In step S204, the photoelectric voltage generating unit generates a voltage for a display, and a memory card may display the amount of memory capacity used, remaining memory capacity, or user information, using the generated voltage via the display unit. The display unit may be, for example, a flat panel display device such as TFT-LCD, PDP, or OLED. The display unit may be a phonetic device such as a speaker thereby indicating the amount of memory capacity used, remaining memory capacity, or user information audibly. The display is provided for a pre-determined time or until the absence of the generated voltage at step S205. The memory card may further include a capacitor adapted to store a voltage or charge, which is not used during the established time, from a voltage generated via photoelectric conversion.

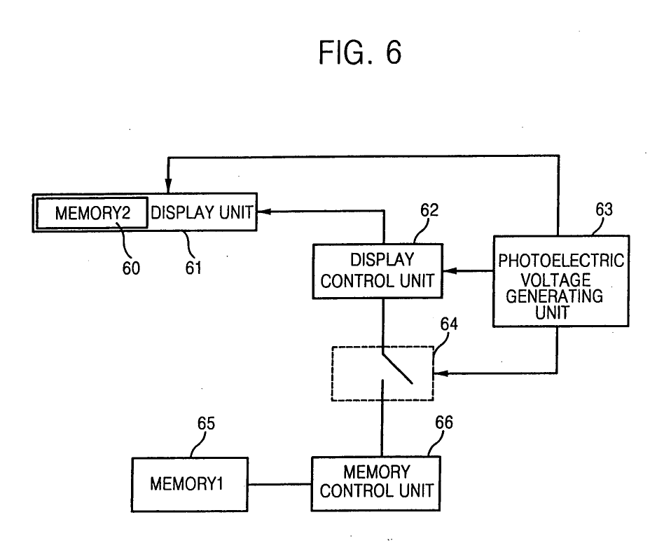

There are various possible methods to display memory card information. FIG. 6 illustrates an exemplary method utilizing an additional memory which may store used memory capacity, remaining memory capacity, or other information, inside the display unit. A display control unit displays relevant information, which is stored in the additional memory through a display unit by using a voltage generated via photoelectric conversion. This exemplary method consumes the least power.

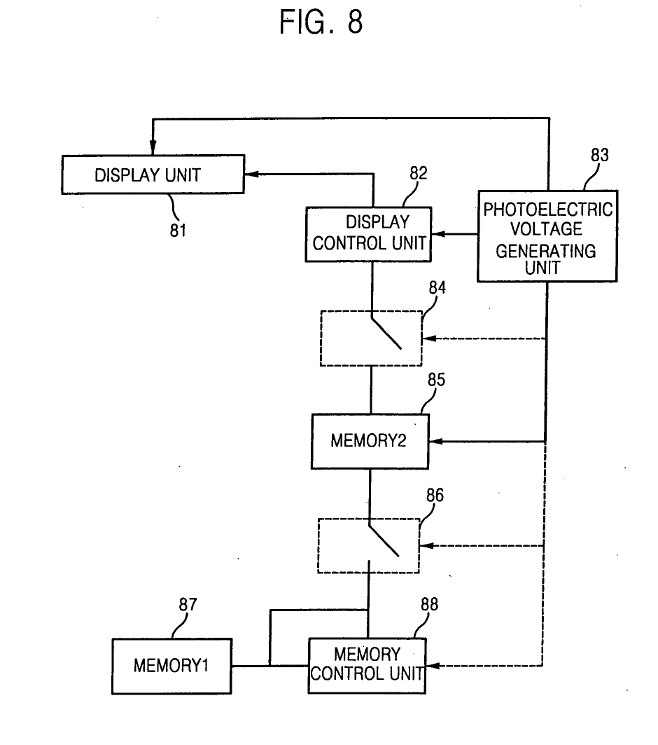

FIG. 8 illustrates an exemplary method utilizing an additional memory which can store used memory capacity, remaining memory capacity, or other information, outside of a display unit. A display control unit displays relevant information, which is stored in the additional memory through a display unit by using a voltage generated via photoelectric conversion. This exemplary method utilizes a memory control unit.

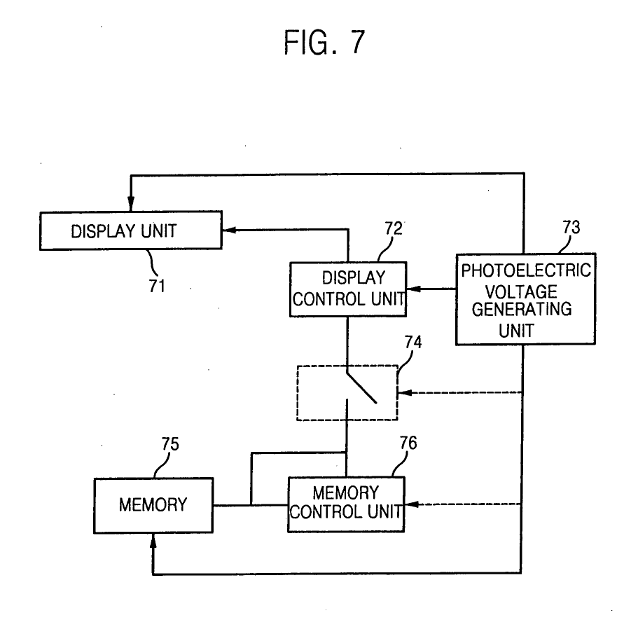

FIG. 7 illustrates an exemplary method to display relevant information using information (such as used memory capacity, remaining memory, or other information), stored directly in a memory through a display control unit and a memory control unit without additional memory (refer to FIG. 7). This method may consume relatively more power than the previous methods however; the problem of power exhaustion may be solved by storing a voltage generated in a photoelectric voltage conversion unit in a predetermined voltage (or charge) storage device, for example, a capacitor, and then using this stored voltage.

FIG. 7 also illustrates a method to display relevant information by using information such as used memory capacity, remaining memory, or the other information, stored directly in a memory through a display control unit without having additional memory or needing to go through a memory control unit. This method consumes less power than the other methods and the problem of power exhaustion may be solved in the same way as mentioned previously.

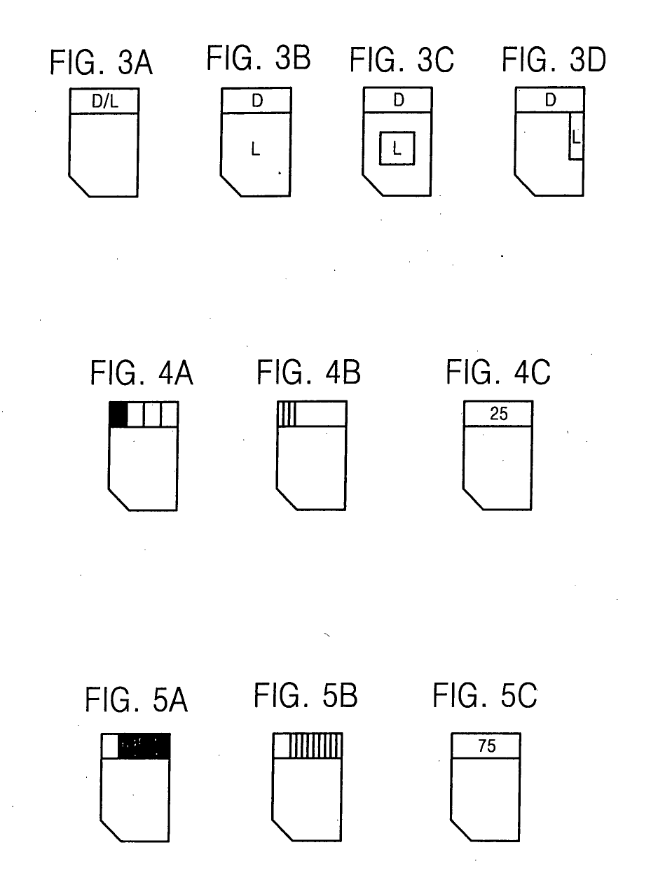

FIGS. 3A to 3D are general plan views of memory cards illustrating arrangements of a display unit and a photoelectric voltage generating unit. In each example illustrated in FIGS. 3A to 3D, every display window D corresponding to a display unit is located on the top section of the memory card. The display window may however, be located anywhere on the memory card. FIG. 3A shows a display window D and a photoelectric conversion unit (or a photoelectric voltage generating unit) L located in the top section of the memory card. By using a pellucid display material at the top of the photoelectric voltage generating unit L, display window D and photoelectric voltage generating unit L may be located in the same place. Therefore, when irradiating light to display window D, memory card information may be confirmed immediately.

FIG. 3B shows the display window D located on the top of the memory card and the photoelectric voltage generating unit L located in the portion of the memory card not occupied by display window D. FIG. 3C shows display window D located on the top of the memory card and the photoelectric voltage generating unit L is located in the middle portion. In this case, by using a pellucid display material, the photoelectric voltage generating unit L and the display window D may be located in the same place.

FIG. 3D shows display window D located on the top portion of the memory card and the photoelectric voltage generating unit L located in the left or right portion of the memory card. By using a pellucid display material, the photoelectric voltage generating unit L and the display window D may be located in the same place.

FIGS. 4A to 4C are plan views illustrating some examples of a display that shows used memory capacity of the memory card. FIG. 4A has a calibration in the display window through which used memory capacity may be displayed. FIG. 4B illustrates an example where used memory capacity is displayed in the form of a bar. FIG. 4C illustrates an example that displays used memory capacity in segment form. This segment form may be suitable for displaying other information via mode conversion by the user.

FIGS. 5A-5C show alternative configurations to display the remaining memory capacity of the memory card converse to that illustrated in FIGS. 4A-4C. For example, FIG. 5A illustrates the unused memory capacity using a colored portion of a bar at the top of the memory card. FIG. 5B illustrates the remaining or unused memory capacity in bar form and FIG. 5C illustrates unused memory capacity in segment form.

FIGS. 6-9 illustrate hardware configurations of the memory card using the above stated photoelectric conversion without the use of a special external power source. FIG. 6 is a block diagram of a memory card including display unit 61, display control unit 62, first memory 65 (memory1), memory control unit 66, and photoelectric voltage generating unit 63. Display unit 61 includes second memory 60 (memory2) used to store necessary information for display. Display control unit 62 is adapted to control the operation of display unit 61. First memory 65 controls the main memory function of the memory card and stores user information. Memory control unit 66 controls the operation of first memory 65. Photoelectric voltage generating unit 63 is adapted to generate a voltage through photoelectric conversion using an external light source. The memory card may further include switch unit 64 adapted to switch the connection between display control unit 62 and memory control unit 66. First memory 65 and second memory 60 may be, for example, non-volatile memory devices such as flash EEPROM.

Photoelectric voltage generating unit 63 generates a voltage via photoelectric conversion and supplies the generated voltage to display unit 61, display control unit 62, and switch unit 64. When switch unit 64 is in an open position, display control unit 62 is disconnected from memory control unit 66 when the memory card is attached to an external device. Therefore, power consumption problems related to adding a display function to the memory card are avoided during normal operation. Switch unit 64 may be automatically opened when the memory card is separated from an external device. Switch unit 64 may be automatically closed when the memory card is attached to an external device which does not require a voltage generated by photoelectric voltage generating unit 63 to switch unit 64. For example, when a display function displays only remaining memory capacity and a user irradiates external light to photoelectric voltage generating unit 63, the generated voltage is supplied to display unit 61 and display control unit 62. As a result, display unit 61 displays the remaining memory capacity of the memory card.

User-set information to be displayed by display unit 61 may be changed. For example, when user information or a user unique number is input into the memory card through a PC or portable device after purchasing the memory card, the information is automatically stored in a particular slot in second memory 60. Second memory 60 has various slots wherein each slot stores user information such as a user telephone number, user unique number, card unique number, remaining memory capacity, etc. This information may be used to locate a particular user if the memory card is misplaced or lost. When a user sets up a switch attached to the outside of the memory card in a special mode and irradiates light to photoelectric voltage generating unit 63, display unit 61 displays relevant user information. In addition, switch unit 64 may remain shut when the memory card is attached to or detached from an external device. Switch unit 64 may be automatically opened when a user irradiates light to photoelectric voltage generating unit 63 whereby a voltage is generated. By controlling at least one of the display unit 61 or display control unit 62, the memory card may be configured to display user information or not display user information. The memory card may further comprise a voltage-saving capacity (not shown) which provides additional voltage to compensate for insufficient voltage when driving at least one of the display unit 61 or the display control unit 62. The voltage-saving capacitor stores a voltage generated whenever light is irradiated on the memory card. This stored voltage may be used to drive at least one of the display unit 61 or display control unit 62 when the stored voltage becomes greater than a level capable of driving either unit. Alternatively, the capacitor may store the remaining voltage after driving either the display unit 61 and/or display control unit 62.

FIG. 7 is a block diagram of a memory card including display unit 71, display control unit 72, memory 75, memory control unit 76 and photoelectric voltage generating unit 73. Display control unit 72 is adapted to control the operation of display unit 71. Memory 75 controls the main memory function of the memory card and stores user information. Memory 75 may be, for example, a non-volatile memory device such as a flash EEPROM, NAND type or NOR type. Memory control unit 76 controls the operation of memory 75 and photoelectric voltage generating unit 73 generates a voltage via photoelectric conversion. The memory card may further include a switch unit 74 to provide a switch connection between display control unit 72 and memory control unit 76. Photoelectric voltage generating unit 73 generates a voltage via photoelectric conversion and supplies the voltage to display unit 71 and display control unit 72. If required, photoelectric voltage generating unit 73 may supply the generated voltage to switch unit 74 as a switching signal.

Switch unit 74 is in an open position when the memory card is attached to an external device and disconnects display control unit 72 from memory control unit 76. Therefore, current consumption problems caused by adding a display function to the memory card are avoided. Switch unit 74 is automatically opened when the memory card is separated from an external device, as well as automatically closed when the memory card is attached to the external device. In this manner, when the memory card is in normal operation, the memory card may operate the display function simultaneously or stop the display function by separately controlling either display unit 71 and/or display control unit 72.

For example, when the remaining memory capacity of the memory card is the only information to be displayed and a user irradiates light to the outside or the surface of the memory card, photoelectric voltage generation unit 73 generates a voltage and allows the remaining memory capacity to be automatically displayed via display unit 71. This is accomplished by supplying the generated voltage to at least one of the display unit 71, display control unit 72, or memory 75. In this manner, displayed information may be changed according to a user set mode. For example, when a user inputs either user information and/or a user unique number into the memory card via a PC or a portable device, the inputted information is automatically stored in a specific slot of memory 75. Memory 75 has various specific slots where each slot stores particular information, for example, a user's telephone number, user unique number, card unique number, remaining memory capacity, etc. This information may be used to locate a particular user if the memory card is misplaced or lost. When a user sets up a switch (not shown) attached to the outside of the memory card and irradiates light to photoelectric voltage generating unit 73, display unit 71 displays relevant user information. Alternatively, switch unit 74 may be kept open when the memory card is attached to or detached from an external device, and may be automatically closed when a user irradiates light onto the memory card. The memory card may further comprise an additional capacitor to store a small voltage or an excess voltage when generated by photoelectric voltage generating unit 73.

FIG. 8 is a block diagram illustrating a memory card including display unit 81, display control unit 82, first memory 87, memory control unit 88, second memory 85, and a photoelectric voltage generating unit 83. Display unit 81 displays information such as used memory capacity, remaining memory capacity, or user information. Display control unit 82 controls display unit 81 and first memory 87 controls the main memory function of a memory card and stores user information. Memory control unit 88 controls first memory 87 and second memory 85 stores the information displayed by display unit 81. First memory 87 and second memory 85 may be, for example a non-volatile memory device such as a flash EEPROM: NAND type or NOR type. Photoelectric voltage generating unit 83 generates a voltage using light transferred from the surface of the memory card via photoelectric conversion.

The memory card may further include first switch unit 84 and second switch unit 86. First switch unit 84 provides a switch connection between display control unit 82 and second memory 85. Second switch unit 86 provides a switch connection between second memory 85 and memory control unit 88. Photoelectric voltage generating unit 83 generates a voltage via photoelectric conversion and supplies the voltage to at least one of the display unit 81, display control unit 82, or second memory 85. If required, photoelectric voltage generating unit 83 may supply the generated voltage to first switch unit 84, second switch unit 86, and memory control unit 88.

Second switch unit 86 separates second memory 85 from memory control unit 88 when the memory card is attached to an external device during normal operation. Therefore, operating problems caused by adding a display function to the memory card during normal operation are avoided. Memory control unit 88 stores necessary information in second memory 85 via second switch unit 86 in a closed position while first switch unit 84 is in an open position. This configuration separates second memory 85 from display control unit 82.

First switch unit 84 may perform the same switching operation as second switch unit 86, or second switch unit 86 may function separately from first switch unit 84. In addition, second switch unit 86 may be automatically opened when the memory card is detached from an external device and automatically closed when the memory card is attached to an external device. In this manner, it is not necessary for the voltage generated by photoelectric voltage generation unit 83 to be supplied to second switch 86 and first switch unit 84 may perform the same switching operation as second switch unit 86, or first switch 84 may remain in the closed position.

When the remaining memory capacity of the memory card is the only information to be displayed, and a user irradiates light to the outside or the surface of the memory card and photoelectric voltage generation unit 83 generates a voltage and allows the remaining memory capacity to be automatically displayed via display unit 81. The information to be displayed may be changed according to a mode set by a user. For example, when a user inputs either user information and/or a user unique number into the memory card via a PC or a portable device, the inputted information is automatically stored in a specific slot of memory 85. Memory 85 has various specific slots where each slot stores particular information, for example, a user's telephone number, user unique number, card unique number, remaining memory capacity, etc. This information may be used to locate a particular user if the memory card is misplaced or lost. When a user sets a switch (not shown) on the outside of the memory card to a specific mode and irradiates light to photoelectric voltage generating unit 73, the memory card may display relevant information on display unit 81.

First switch unit 84 and second switch unit 86 may remain closed without switching when the memory card is attached to an external device and may be opened automatically when a user irradiates light onto the memory card. In this case, the memory card, during its normal operation, operates a display function simultaneously or may stop the display function by separately controlling at least one of the display unit 81 or display control unit 82. The memory card may further comprise an additional capacitor to store a small voltage or an excess voltage generated in photoelectric voltage generating unit 83.

As described above, the present invention shows that a memory card itself may generate a voltage without having an external power supply via a photoelectric conversion. It may supply minimum information such as the amount of used memory capacity, remaining memory capacity, or additional information related to a user. Even without the presence of a power supply, the memory card may display minimum information such as used memory capacity, remaining memory capacity, or additional information related to a user by using its own power generated according to a user's selection through an addition of simple components.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

What is claimed is:

1. A method of displaying information of a memory card using an external light source comprising:
generating a voltage corresponding to light irradiated externally through photoelectric conversion; and
displaying information, stored in advance, via a display unit of the memory card using said generated voltage.

2. The method of claim 1, wherein displaying the information further comprises selecting a portion of said information stored in advance and displaying the selected information through the display unit.

3. The method of claim 1, wherein generating the voltage further comprises accumulating the generated voltage to a capacitor until the voltage is equal to or greater than a voltage associated for driving the display unit.

4. The method of claim 1, wherein said information stored in advance includes at least one of remaining memory capacity, used memory capacity, user information, user unique number, or device unique number.

5. The method of claim 1, further comprising:
displaying the information stored in advance through the display unit and turning the display unit off after a predetermined time has lapsed.

6. The method of claim 5, wherein generating a voltage results in leftover voltage, said method further comprising storing said leftover voltage in a capacitor after the display unit is off.

7. A memory card having an information display function using an external light source, the memory card comprising:
a first memory responsible for a main memory function of the memory card;
a memory control unit adapted to control operation of said first memory;
a photoelectric voltage generation unit adapted to generate a voltage corresponding to light irradiated externally through photoelectric conversion;
a display unit having a second memory adapted to store predetermined information and adapted to display said stored information using the voltage generated by said photoelectric voltage generation unit; and
a display control unit adapted to control operation of said display unit.

8. The memory card of claim 7, further comprising a switch unit connecting and disconnecting said memory control unit and said display control unit.

9. The memory card of claim 7, further comprising a switching unit configured to automatically turn on/off a connection between said memory control unit and said display control unit when the memory card is attached to or detached from an external device.

10. The memory card of claim 7, further comprising a capacitor storing a voltage generated by said photoelectric voltage generation unit.

11. The memory card of claim 7, further comprising a selection unit selecting one of the predetermined information set in advance by a user.

12. The memory card of claim 7, wherein the predetermined information comprises at least one of remaining memory capacity of said memory card, used memory capacity of said memory card, user information, user unique number, or unique number of said memory card.

13. A memory card having a capability of displaying information using an external light source, the memory card comprising:
a memory responsible for a main memory function of the memory card, and storing information set in advance in a specific portion of said memory;
a memory control unit adapted to control operation of said memory;
a photoelectric voltage generation unit adapted to generate a voltage in response to light irradiated onto said memory card externally through photoelectric conversion;
a display unit adapted to display the information set in advance stored in the memory according to a voltage generated by said photoelectric voltage generation unit; and
a display control unit adapted to control operation of said display unit.

14. The memory card of claim 13, further comprising a switching unit connected between said memory control unit and said display control unit.

15. The memory card of claim 13, further comprising a switching unit connected between said memory control unit and said display control unit, said switching unit capable of automatically turning on or off when the memory card is attached to or detached from an external device, respectively.

16. The memory card of claim 13, further comprising a capacitor for storing a voltage generated by said photoelectric voltage generating unit when a voltage generated by said photoelectric voltage generating unit is less than a voltage for driving said display unit.

17. The memory card of claim 13, further comprising a capacitor for storing a voltage generated by said photoelectric voltage generating unit when a voltage generated by said photoelectric voltage generating unit remains after said display unit is turned off.

18. The memory card of claim 13, further comprising a selection unit selecting one of the pieces of information set in advance in said specific portion of said memory;.

19. The memory card of claim 13, wherein the information set in advance comprises at least one of remaining memory capacity of said memory card, used memory capacity said memory card, user information, user unique number, or unique number of said memory card. rd

20. A memory card having an information display function utilizing an external light source, the memory card comprising:
a first memory responsible for a main memory function of said memory card;
a memory control unit adapted to control operation of said first memory;
a second memory adapted to store information set in advance;
a photoelectric voltage generating unit adapted to generate a voltage corresponding to light irradiated externally via photoelectric conversion;
a display unit adapted to display said information stored in said second memory using a voltage generated in said photoelectric voltage generation unit; and
a display control unit adapted to control operation of said display unit.

21. The memory card of claim 20, further comprising:
a first switch unit connected between said display control unit and said second memory; and
a second switch unit connected between said second memory and said memory control unit.

22. The memory card of claim 20, further comprising:
a first switch unit connected between said display control unit and said second memory, said first switch unit turned on and off automatically when said memory card is attached to or detached from an external device; and
a second switch unit connected between said second memory and said memory control unit, said second switch unit turned on and off automatically when said memory card is attached to or detached from said external device.

23. The memory card of claim 20, further comprising a capacitor configured to store a voltage generated in said photoelectric voltage generating unit when said generated voltage is less than a voltage for driving said display unit.

24. The memory card of claim 20, further comprising a capacitor configured to store a voltage generated in said photoelectric voltage generating unit when said generated voltage remains after said display unit is shut off.

25. The memory card of claim 20, wherein the information set in advance comprises at least one of remaining memory capacity of said memory card, used memory capacity of said memory card, user information, user unique number, or unique number of said memory card.
